(19) United States
(12) Patent Application Publication
(10) Pub. No.: US 2013/0016519 A1
(43) Pub. Date: Jan. 17, 2013

(54) LIGHT SOURCE MODULE

(71) Applicant: Heng-Sheng KUO, New Taipei City (TW)

(72) Inventor: Heng-Sheng KUO, New Taipei City (TW)

(21) Appl. No.: 13/183,425

(22) Filed: Jul. 14, 2011

(51) Int. Cl. F21V 29/00; H01L 33/02

(52) U.S. Cl. 362/555; 362/580

(57) ABSTRACT

A light source module includes a casing, a light-guiding rod, a light-emitting assembly and a heat-dissipating reflective shroud. The casing has a chamber and a transparent opening in communication with the chamber. The light-guiding rod has a light-exiting surface and a light-transmitting surface opposite to the light-exiting surface. The light-guiding rod is disposed in the chamber with the light-exiting surface facing the transparent opening. The light-emitting assembly is provided on one side of the light-guiding rod to emit light toward the interior of the light-guiding rod. The heat-dissipating reflective shroud is assembled with the casing to cover the light-transmitting surface of the light-guiding rod. The interior of the heat-dissipating reflective shroud has a reflective surface for reflecting the light passing through the light-transmitting surface back toward the light-exiting surface to exit the transparent opening. The heat-dissipating reflective shroud has double effects of heat dissipation and light reflection.

### BACKGROUND OF THE INVENTION

1. Field of the Invention

The present invention relates to a light source module, and in particular to a light source module having a light-guiding rod.

2. Description of Prior Art

With the advancement of science and technology, various kinds of light source modules are developed. Especially, various office apparatuses such as a photocopier, a scanner, a multifunction office peripheral device are provided therein with a linear light source module, thereby generating a linear illumination area. The traditional linear light source module is configured to generate a forward illumination and has a higher cost. Further, the thickness of the forward illumination type light source module cannot be reduced further, which cannot conform to the requirement for compact design.

Thus, a side illumination type light source module is proposed, in which a light-emitting element is disposed on a side surface of a light-guiding rod, so that the light emitted by the light-emitting element can enter one side of the light-guiding rod. By this arrangement, the length of the light-emitting element is reduced. Further, the light-guiding rod makes the light uniform. Further, arranging the light-emitting element on one side of the light-guiding rod conforms to the requirement for compact design. However, in a conventional linear light source module with changeable light-emitting angle, a heat-dissipating element and a fastener have to be additionally mounted. The fastener is configured to fix the heat-dissipating element to the light-emitting element for dissipating the heat generated by the light-emitting element to the outside. As a result, such a conventional light source module has more components, and the assembly and production thereof are more complicated.

### SUMMARY OF THE INVENTION

The present invention is to provide a light source module with a simple structure, lower cost, and a better heat-dissipating effect.

The present invention provides a light source module, including:

a casing having a chamber and a transparent opening in communication with the chamber;

a light-guiding rod having a light-exiting surface and a light-transmitting surface opposite to the light-exiting surface, the light-guiding rod being disposed in the chamber with the light-exiting surface facing the transparent opening;

a light-emitting assembly provided on one side of the light-guiding rod to emit light toward the interior of the light-guiding rod; and

a heat-dissipating reflective shroud assembled with the casing to cover the light-transmitting surface of the light-guiding rod, the interior of the heat-dissipating reflective shroud having a reflective surface for reflecting the light passing through the light-transmitting surface back toward the light-exiting surface to exit the transparent opening.

In comparison with prior art, the present invention has advantageous features as follows.

According to the present invention, since the light source module merely includes a casing, a light-guiding rod, a light-emitting assembly, and a heat-dissipating reflective shroud, it is not necessary to provide a heat-dissipating element and a fastener because the heat-dissipating reflective shroud can generate double effects of heat dissipation and light reflection. Thus, the present invention has a simple structure, a reduced cost and the assembly and production thereof are easier.

Since the present invention utilizes the heat-dissipating reflective shroud to dissipate the heat generated by the light-emitting assembly, the heat-dissipating area is large enough to dissipate the heat rapidly, thereby increasing the light-emitting efficiency of the light-emitting elements, such as LEDs.

### BRIEF DESCRIPTION OF DRAWING

FIG. 1 is an exploded perspective view of the present invention;

FIG. 2 is another exploded perspective view of the present invention;

FIG. 3 is an assembled perspective view of the present invention;

FIG. 4 is an assembled cross-sectional view of the present invention; and

FIG. 5 is a cross-sectional view showing the operating principle of the present invention.

### DETAILED DESCRIPTION OF THE INVENTION

The detailed description and technical contents of the present invention will become apparent with the following detailed description accompanied with related drawings. It is noteworthy to point out that the drawings is provided for the illustration purpose only, but not intended for limiting the scope of the present invention.

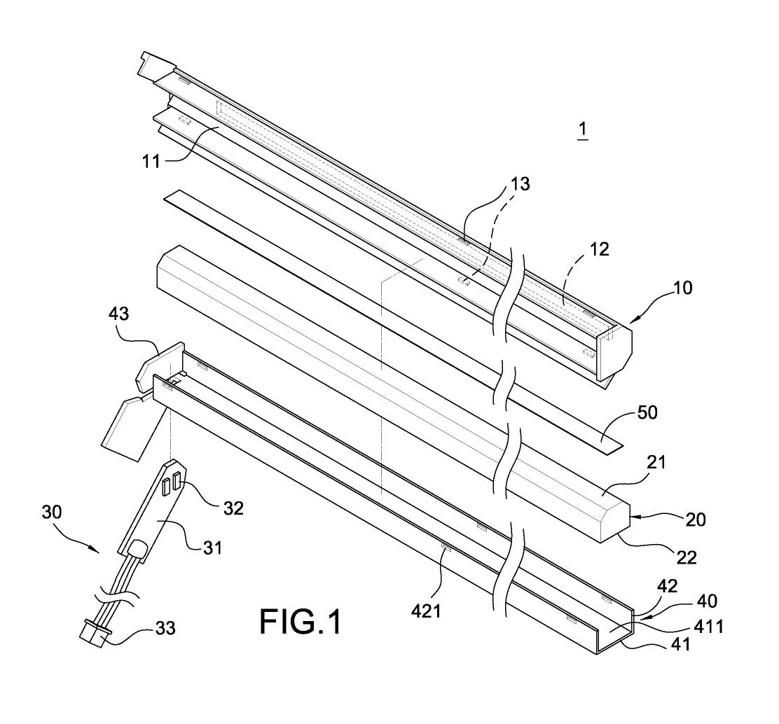

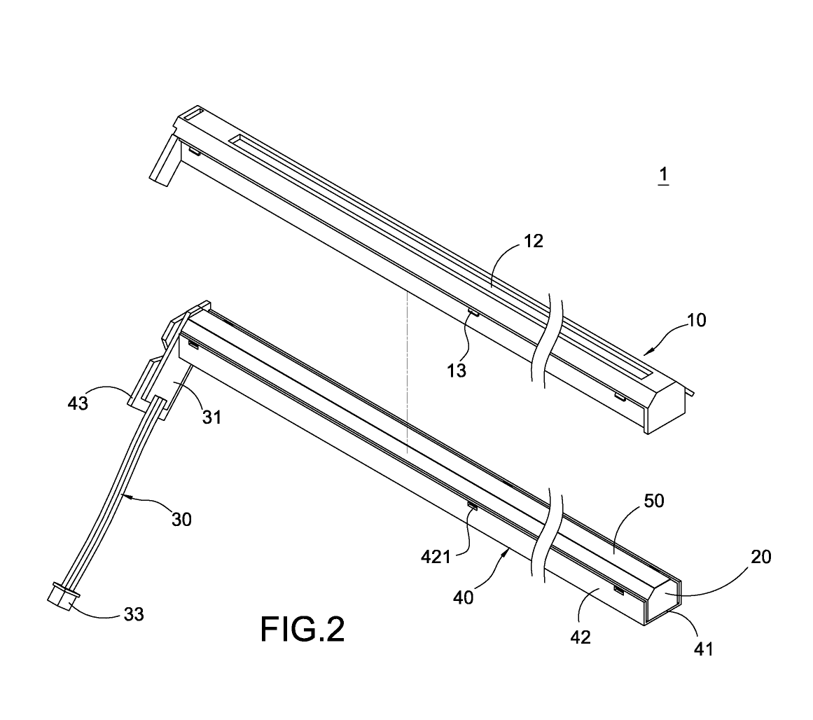

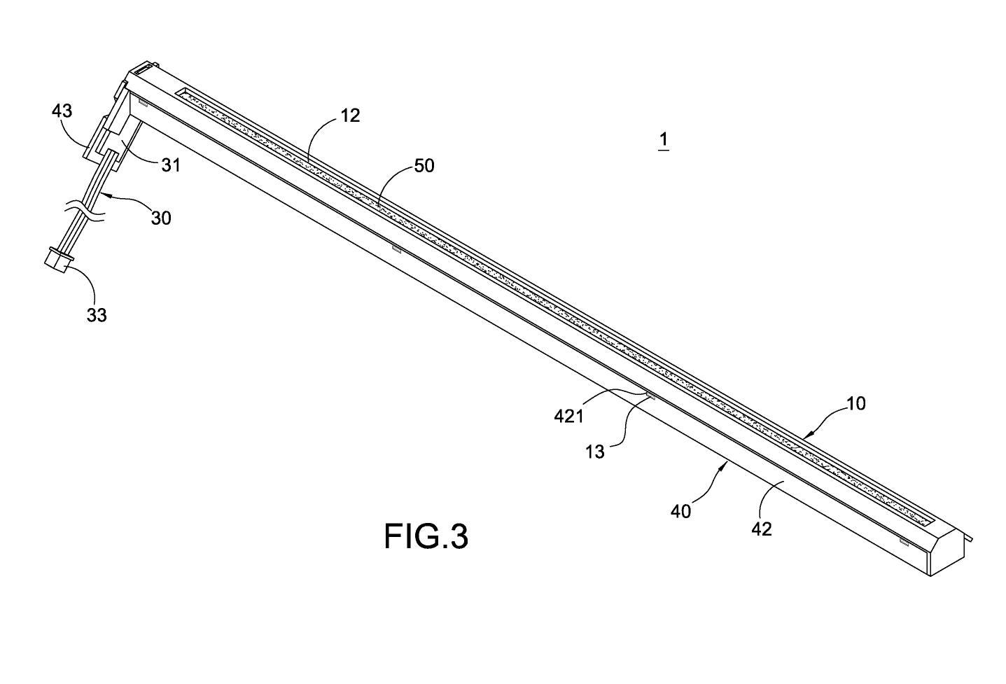

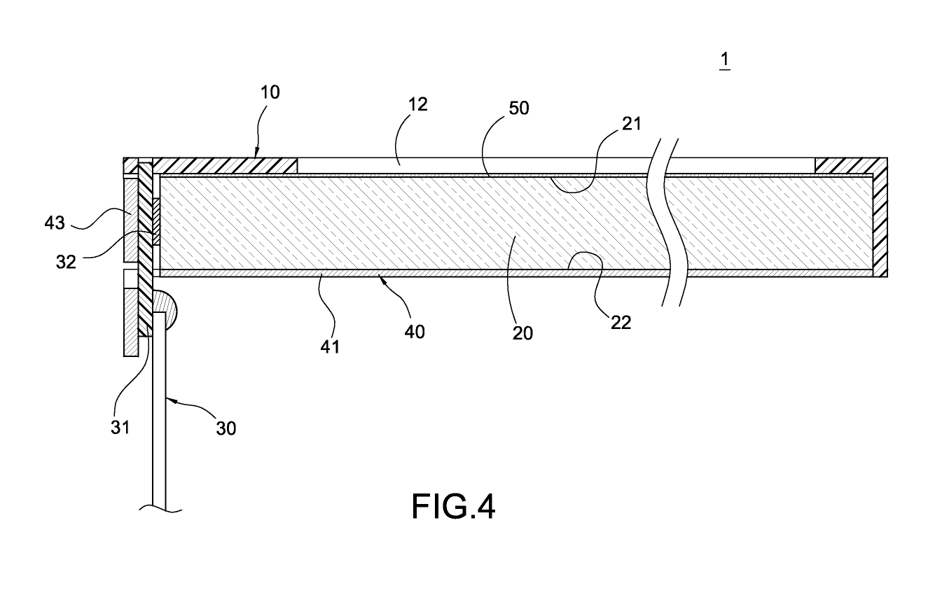

Please refer to FIGS. 1 to 4. The present invention provides a light source module 1, which includes a casing 10, a light-guiding rod 20, a light-emitting assembly 30, and a heat-dissipating reflective shroud 40.

The casing 10 has a chamber 11 and a transparent opening 12 in communication with the chamber 11. In the embodiment of FIG. 1, the transparent opening 11 is formed into an elongate strip shape in parallel with a longitudinal axial line of the casing 10. The inner walls of the casing 10 are made to become reflective surfaces.

The light-guiding rod 20 has a light-exiting surface 21 and a light-transmitting surface 22 opposite to the light-exiting surface 21. The light-guiding rod 20 is disposed in the chamber 11 with the light-exiting surface 21 facing the transparent opening 12. The light-guiding rod 20 is formed into a polygonal post. The profile of the chamber 11 corresponds to the profile of the light-guiding rod 20. In the embodiment of FIG. 1, the light-guiding rod 20 is formed into a pentagonal post. The light-guiding rod 20 is made of transparent material, such as glass or transparent plastic material. Further, optionally, the light-exiting surface 21 of the light-guiding rod 20 is adhered with a light-enhancing piece 50 for enhancing the uniformity of the light. The light-enhancing piece 50 is made of transparent plastic material.

The light-emitting assembly 30 is disposed on one side of the light-guiding rod 20 to emit light toward the interior of the light-guiding rod 20. The light-emitting assembly 30 comprises a circuit board 31 and a plurality of light-emitting elements 32 arranged on the circuit board 31. The light-emitting elements 32 may be light-emitting diodes (LEDs) of a color selected from the visible spectrum. Alternatively, the light-emitting elements 32 may be infrared or ultraviolet light sources. The light-emitting diodes may emit light of green, yellow, blue, red, or white color, so that the light-emitting assembly 30 has a large range in the intensity and brightness of the light. Further, a plug 33 is electrically connected onto the circuit board 31 for allowing an external electric power to be inputted therein.

The heat-dissipating reflective shroud 40 is made of material with high heat conductivity. Especially, aluminum is excellent in heat conductivity. The heat-dissipating reflective shroud 40 is assembled with the casing 40 to cover the light-transmitting surface 22 of the light-guiding rod 20. The heat-dissipating reflective shroud 40 is constituted of a bottom plate 41 and two side plates 42 on both sides of the bottom plates 41. Each of the side plates 42 is provided with at least one engaging hole 421. The casing 10 is provided with at least one hook 13 to be engaged with the engaging hole 421. In this way, the heat-dissipating reflective shroud 40 can be firmly assembled with the casing 10 in such a manner that the light-guiding rod 20 is disposed between the heat-dissipating reflective shroud 40 and the casing 10. The bottom plate 41 is formed with a reflective surface 411 adjacent to the light-transmitting surface 22 of the light-guiding rod 20. The reflective surface 411 reflects the light passing through the light-transmitting surface 22 of the light-guiding rod 20 back toward the light-exiting surface 21 to exit the transparent opening 12. By this arrangement, the light-reflecting efficiency is enhanced, the brightness and utilization rate of the light are increased.

Since the light-emitting assembly 30 is disposed on one side of the light-guiding rod 20, one end of the heat-dissipating reflective shroud 40 is provided with a mounting plate 43 at a position corresponding to the light-emitting assembly 30. The light-emitting assembly 30 is fixed onto the mounting plate 43.

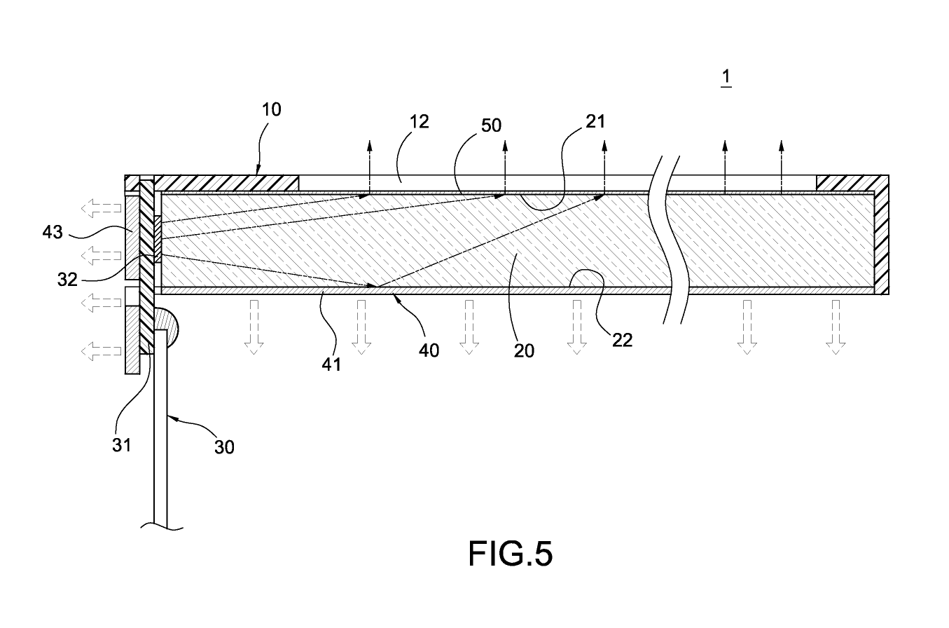

Please refer to FIG. 5. When the light-emitting element 32 emits light from one side of the light-guiding rod 20, a portion of the light emitted by the light-emitting element 32 exits the transparent opening 12 directly, and the other portion is reflected by the reflective surface 411 of the bottom plate 41 of the heat-dissipating reflective shroud 40 back toward the transparent opening 12. Further, the heat generated by the light-emitting elements 32 is dissipated to the outside via the heat-dissipating reflective shroud 40.

In comparison with prior art, the present invention has advantageous features as follows.

According to the present invention, since the light source module 1 merely includes a casing 10, a light-guiding rod 20, a light-emitting assembly 30, and a heat-dissipating reflective shroud 40, it is not necessary to provide a heat-dissipating element and a fastener because the heat-dissipating reflective shroud 40 can generate double effects of heat dissipation and light reflection. Thus, the present invention has a simple structure, a reduced cost and the assembly and production thereof are easier.

Since the present invention utilizes the heat-dissipating reflective shroud 40 to dissipate the heat generated by the light-emitting assembly 30, the heat-dissipating area is large enough to dissipate the heat rapidly, thereby increasing the light-emitting efficiency of the light-emitting elements.

Although the present invention has been described with reference to the foregoing preferred embodiments, it will be understood that the invention is not limited to the details thereof. Various equivalent variations and modifications can still occur to those skilled in this art in view of the teachings of the present invention. Thus, all such variations and equivalent modifications are also embraced within the scope of the invention as defined in the appended claims.

What is claimed is:

1. A light source module, including:
a casing having a chamber and a transparent opening in communication with the chamber;
a light-guiding rod having a light-exiting surface and a light-transmitting surface opposite to the light-exiting surface, the light-guiding rod being disposed in the chamber with the light-exiting surface facing the transparent opening;
a light-emitting assembly provided on one side of the light-guiding rod to emit light toward the interior of the light-guiding rod; and
a heat-dissipating reflective shroud assembled with the casing to cover the light-transmitting surface of the light-guiding rod, the interior of the heat-dissipating reflective shroud having a reflective surface for reflecting the light passing through the light-transmitting surface back toward the light-exiting surface to exit the transparent opening.

2. The light source module according to claim 1, wherein the heat-dissipating reflective shroud includes a bottom plate and two side plates on both sides of the bottom plate, each of the side plates is provided with at least one engaging hole, and the casing is provided with at least one hook to be engaged with the engaging hole.

3. The light source module according to claim 2, wherein the reflective surface is formed on the bottom plate adjacent to the light-transmitting surface of the light-guiding rod.

4. The light source module according to claim 3, wherein one end of the heat-dissipating reflective shroud is provided with a mounting plate at a position corresponding to the light-emitting assembly, and the light-emitting assembly is fixed onto the mounting plate.

5. The light source module according to claim 4, wherein the transparent opening is formed into an elongate strip shape in parallel with a longitudinal axial line of the casing.

6. The light source module according to claim 5, wherein the light-guiding rod is formed into a polygonal post, and the profile of the chamber corresponds to the profile of the light-guiding rod.

7. The light source module according to claim 6, further including a light-enhancing piece adhered onto the light-exiting surface of the light-guiding rod.

8. The light source module according to claim 7, wherein the light-emitting assembly comprises a circuit board and a plurality of light-emitting elements arranged on the circuit board.

9. The light source module according to claim 8, wherein the light-emitting elements are light-emitting diodes.

10. The light source module according to claim 1, wherein the heat-dissipating reflective shroud is a metallic component with high heat conductivity.
